(19) United States
(12) Patent Application Publication
(10) Pub. No.: US 2017/0357126 A1
(43) Pub. Date: Dec. 14, 2017

(54) DISPLAY PANEL AND DISPLAY DEVICE

(71) Applicant: BOE Technology Group Co., Ltd., Beijing (CN)

(72) Inventor: Lijun ZHAO, Beijing (CN)

(21) Appl. No.: 15/544,739

(22) PCT Filed: Mar. 9, 2016
(86) PCT No.: PCT/CN2016/075981

§ 371 Date: Jul. 19, 2017

(30) Foreign Application Priority Data
Apr. 29, 2015 (CN) 201510211989.5

(51) Int. Cl. G02F 1/1335; H01L 51/52; G02F 1/1343; G02F 1/1368; H01L 27/32

(52) U.S. Cl. CPC G02F 1/133603; G02F 1/133553; G02F 1/133528; G02F 1/133605; H01L 51/5218; G02F 1/134363; G02F 2001/133531; G02F 2001/133567; H01L 27/3244; G02F 2201/44; G02F 2001/133626; H01L 27/3232; G02F 1/1368

(57) ABSTRACT

The present disclosure provides a display panel and a display device. The display panel comprises a first substrate, a liquid crystal layer, a second substrate and a polarizer which are stacked sequentially; a light reflection layer and a plurality of organic light-emitting units being provided on the first substrate, wherein the plurality of organic light-emitting units are located at a side of the light reflection layer close to the liquid crystal layer; the second substrate is configured to control deflections of liquid crystal molecules in the liquid crystal layer, and the second substrate comprises a plurality of sub-pixel regions. The display panel provided by the embodiment of the present disclosure achieves a transmission-type displaying in a case that the display signal is input to the first substrate, and achieves a reflection-type displaying in a case that the display signal is input to the second substrate.

### CROSS-REFERENCE TO RELATED APPLICATION

This application claims the benefit and priority of Chinese Patent Application No. 201510211989.5, filed on Apr. 29, 2015, the disclosure of which is incorporated herein by reference in its entirety.

### FIELD

The embodiments of the present disclosure relate to a field of display, and particularly, to a display panel and a display device.

### BACKGROUND

Currently, the liquid crystal display devices can be classified into a transmission-type liquid crystal display device and a reflection-type liquid crystal display device depending on their principles of the use of a light source. In the transmission-type liquid crystal display device, a backlight source is usually required, which is provided on its back for illumination. However, the energy consumption of the transmission-type liquid crystal display device is large because the energy consumption of the backlight source is high. In addition, in a case that the ambient light is strong, the contrast ratio of the liquid crystal display panel is low, so the display effect is poor. The reflection-type liquid crystal display device may not need the backlight source and the energy consumption is low, thus it is suitable for the circumstances of strong ambient light, but the display quality will be degraded in a case that the ambient light is weak.

The above two types of display devices may achieve good display qualities only under specific environmental conditions, and a display product adaptive to different environmental conditions is urgently needed as people's requirement of the display product is improved.

### SUMMARY

The embodiments of the present disclosure provide a display panel and a display device, which may realize a switching between a transmission-type display mode and a reflection-type display mode as required.

According to an embodiment of the present disclosure, there is provided a display panel, which includes a first substrate, a liquid crystal layer, a second substrate and a polarizer which are stacked sequentially;

a light reflection layer and a plurality of organic light-emitting units being provided on the first substrate, wherein the plurality of organic light-emitting units are located at a side of the light reflection layer close to the liquid crystal layer;

the second substrate is configured to control deflections of liquid crystal molecules in the liquid crystal layer, so as to control a polarization state of light passing through the liquid crystal layer.

In an example, the second substrate comprises a plurality of sub-pixel regions, each of which is provided with a thin film transistor and an electrode structure connected thereto; the electrode structure is configured to generate an electric field for controlling deflections of liquid crystal molecules in a region corresponding to the sub-pixel region in the liquid crystal layer.

In an example, the organic light-emitting unit comprises an organic light-emitting layer, a first electrode layer provided at a side of the organic light-emitting layer close to the liquid crystal layer, and a second electrode layer provided at a side of the organic light-emitting layer away from the liquid crystal layer.

In an example, the second electrode layer and the light reflection layer are the same structure, so as to multiplex the second electrode layer as the light reflection layer.

In an example, the plurality of organic light-emitting units are white organic light-emitting units.

In an example, the sub-pixel regions on the second substrate directly face the organic light-emitting units on the first substrate one by one.

In an example, the sub-pixel regions on the second substrate and the organic light-emitting units on the first substrate have the same shape and size.

In an example, the display panel further comprises a third substrate provided at a light-outgoing side of the first substrate; the third substrate comprises a plurality of color filter units which directly face the organic light-emitting units on the first substrate one by one.

In an example, the third substrate further comprises color filter units having at least three colors which are arranged on the third substrate periodically and repeatedly.

In an example, the third substrate further comprises a black matrix layer for separating the plurality of color filter units from each other.

In an example, the third substrate is provided at a side of the second substrate away from the liquid crystal layer.

In an example, the plurality of organic light-emitting units are color organic light-emitting units.

In an example, the first substrate comprises organic light-emitting units having at least three colors which are arranged on the first substrate periodically and repeatedly.

In an example, the display panel further comprises a control unit configured to input a display signal to the first substrate or the second substrate, so that the display panel operates under a first display mode in a case that the display signal is input to the first substrate, and the display panel operates under a second display mode in a case that the display signal is input to the second substrate.

In an example, the first display mode is a transmission-type display mode, and the second display mode is a reflection-type display mode.

According to another embodiment of the present disclosure, there is further provided a display device, comprising any of the above display panels.

The display panel provided by the embodiment of the present disclosure can realize a switching between the transmission-type display mode and the reflection-type display mode as required. Specifically, a transmission-type displaying of the display panel can be achieved in a case that the display signal is input to the first substrate, and a reflection-type displaying of the display panel can be achieved in a case that the display signal is input to the second substrate.

### DRAWINGS

FIG. 1 illustrates a schematic diagram of a display panel provided by an embodiment of the present disclosure;

FIG. 2 illustrates a schematic diagram of the display panel as illustrated in FIG. 1 under a transmission-type display mode;

FIG. 3 illustrates a schematic diagram of the display panel as illustrated in FIG. 1 in a bright displaying state under a reflection-type display mode;

FIG. 4 illustrates a schematic diagram of the display panel as illustrated in FIG. 1 in a dark displaying state under a reflection-type display mode;

FIG. 5 illustrates a schematic diagram of an organic light-emitting unit provided by an embodiment of the present disclosure;

FIG. 6 illustrates a schematic diagram of another display panel provided by an embodiment of the present disclosure; and

FIG. 7 illustrates a schematic structural diagram of a display panel comprising a control unit.

### DETAILED DESCRIPTION

Next, the present disclosure will be further described in details with reference to the drawings and embodiments. The following embodiments are used to describe the present disclosure, rather than limiting the scope of the present disclosure.

An embodiment of the present disclosure provides a display panel, which includes a first substrate, a liquid crystal layer, a second substrate and a polarizer which are stacked sequentially;

a light reflection layer and a plurality of organic light-emitting units is provided on the first substrate, wherein the plurality of organic light-emitting units are located at a side of the light reflection layer close to the liquid crystal layer;

the second substrate is configured to control deflections of liquid crystal molecules in the liquid crystal layer, and the second substrate comprises a plurality of sub-pixel regions.

The display panel provided by the embodiment of the present disclosure may be switched between two display modes by controlling a display signal to be input to the first display substrate and the second display substrate. For example, a transmission-type displaying of the display panel can be achieved in a case that the display signal is input to the first substrate, and a reflection-type displaying of the display panel can be achieved in a case that the display signal is input to the second substrate.

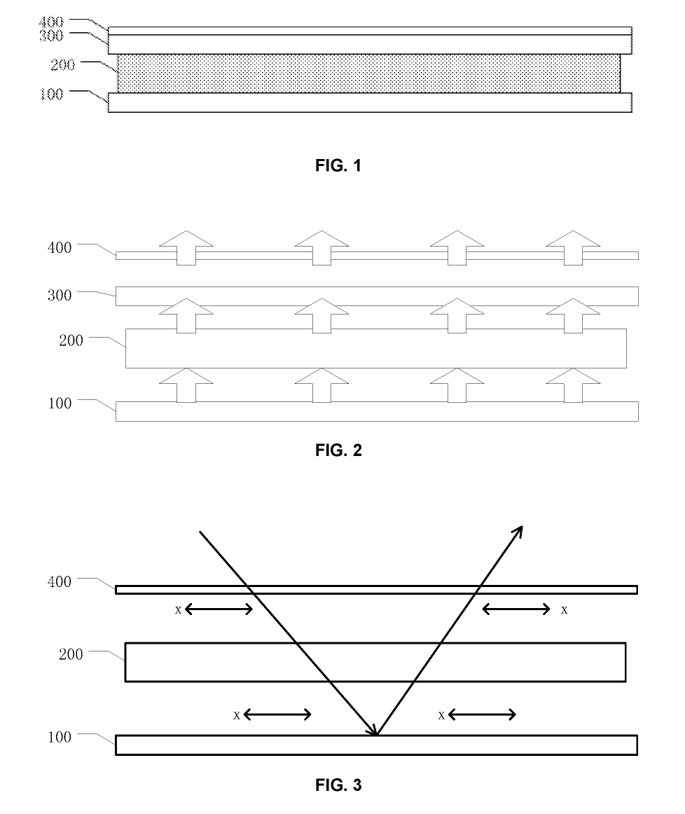

Referring to FIG. 1, which illustrates a schematic diagram of a display panel provided by an embodiment of the present disclosure, the display panel includes a first substrate 100, a liquid crystal layer 200, a second substrate 300 and a polarizer 400 which are stacked sequentially, and an orientation layer (not illustrated) may further be provided on an upper side and a lower side of the liquid crystal layer 200, respectively. As an example, the liquid crystal layer 200 is provided on the first substrate 100, the second substrate 300 is provided on the liquid crystal layer 200, and the polarizer 400 is provided on the second substrate 300.

In one embodiment, the first substrate 100 may be an OLED substrate, on which a plurality of organic light-emitting units in a matrix arrangement are provided, and each of the organic light-emitting units is provided with a respective thin film transistor (TFT). In a case that a display signal is input to the first substrate, the organic light-emitting units thereon presents a bright or dark state according to the input display signal, so as to display corresponding picture.

Further, a light reflection layer is further provided at a side of each of the organic light-emitting units away from the liquid crystal layer, and configured to reflect natural light from the outside, so that the reflected light serves as backlight of the display panel according to the embodiment of the present disclosure.

The second substrate 300 is configured to control deflections of liquid crystal molecules in the liquid crystal layer, and comprises a plurality of sub-pixel regions. In one embodiment, the second substrate is provided with gate lines and data lines intersecting each other, and divided into a plurality of sub-pixel regions by the gate lines and the data lines. In one embodiment, each of the sub-pixel regions is provided with a TFT and a transparent electrode structure connected thereto. Deflection states of liquid crystal molecules in corresponding region of the liquid crystal layer may be controlled through an electric field generated by the electrode structure, so a polarization state of light passing through the region in the liquid crystal layer may be controlled. It shall be appreciated that other embodiments are also feasible.

The display panel provided by the embodiments of the present disclosure may achieve either a transmission-type displaying or a reflection-type displaying, as described in the above embodiments or to be further described in details.

Specifically, In a case that the display signal is input to the first substrate 100, as illustrated in FIG. 2, the first substrate emits light by means of the organic light-emitting units thereon. In addition, as the light exiting from the first substrate is natural light, it may be orderly transmitted through the liquid crystal layer 200, the second substrate 300 and the polarizer 400 and then emergent, thereby achieving the transmission-type displaying of the display panel.

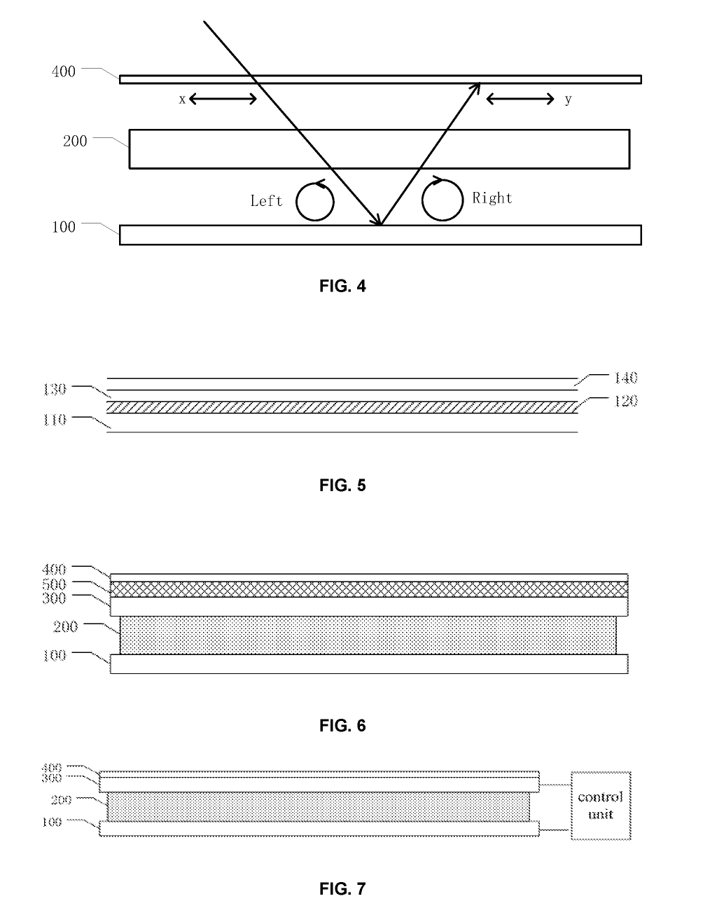

In a case that the display signal is input to the second substrate 300, the first substrate 100 does not operate, and the electrode structure on each sub-pixel regions of the second substrate 300 generates different electric fields according to the input display signal, so that liquid crystal molecules in different regions of the liquid crystal layer are in different deflection states, thereby controlling the polarization state of light passing through the liquid crystal layer. Specifically, for example, an electrode structure generating an electric field in a horizontal mode is provided on the second substrate, given that a transmission axis of the polarizer is in direction x, natural light from the outside is transmitted through the polarizer 400 to form linear polarized light in direction x, and then incident to the liquid crystal layer 200. In a case that the electrode structure in the sub-pixel region does not generate any electric field, the state of liquid crystal molecules in the liquid crystal layer is not changed, and the liquid crystal layer 200 at that position may not change the polarization state of the linear polarized light transmitted therethrough. Therefore, the linear polarized light in direction x is still linear polarized light in direction x after passing through the liquid crystal layer 200, then reflected back to the liquid crystal layer 200 by the light reflection layer on the first substrate 100, and is still linear polarized light in direction x after passing through the liquid crystal layer 200, so it may be emergent through the polarizer 400, so that the sub-pixel region may be under a bright displaying state. In a case that the electrode structure in the sub-pixel region generates a horizontal electric field, liquid crystal molecules in the liquid crystal layer at corresponding position are rotated under the effect of the electric field, and their torsion angles meet the birefringence condition, so that the linear polarized light incident into the liquid crystal layer is changed to circular polarized light after passing through the liquid crystal layer. For example, as illustrated in FIG. 4, the linear polarized light in direction x generated by the polarizer 400 forms left-handed circular polarized light after being transmitted through the liquid crystal layer 200, then incident to the light reflection layer on the first substrate 100 and reflected by the light reflection layer to form right-handed circular polarized light, which is transmitted through the liquid crystal layer 300 to form linear polarized light in direction y. Since the linear polarized light in direction y cannot be transmitted through the polarizer 400, a dark displaying state of the sub-pixel region is achieved.

It can be seen, in a case that the display signal is input to the first substrate, a transmission-type displaying of the display panel may be achieved; and in a case that the display signal is input to the second substrate, the bright or dark state of the sub-pixel region of the second substrate may be controlled by controlling the direction of the electric field generated by the electrode structure on the second substrate, and a reflection-type displaying of the display panel may be achieved.

In one embodiment, as illustrated in FIG. 7, the display panel may further comprise a control unit through which the display signal may be input to the first substrate or the second substrate. In a case that the display signal is input to the first substrate, the display panel operates under a first display mode; and in a case that the display signal is input to the second substrate, the display panel operates under a second display mode. In one example, the first display mode is a transmission-type display mode, and the second display mode is a reflection-type display mode.

In one embodiment, the above light reflection layer may be individually formed on the first substrate. In another embodiment, the electrode layer in the organic light-emitting unit of the first substrate may be multiplexed as the light reflection layer, i.e., the light reflection layer and the electrode layer in the organic light-emitting unit of the first substrate may be the same structure. As illustrated in FIG. 5, each of the organic light-emitting units on the first substrate 100 comprises a base 110, an organic light-emitting layer 130, a first electrode layer 140 provided at a side of the organic light-emitting layer 130 close to the liquid crystal layer, a second electrode layer 120 provided at a side of the organic light-emitting layer 130 away from the liquid crystal layer, wherein the first electrode layer 140 may be made of a transparent conductive material, such as ITO, and the second electrode layer 120 may be made of a conductive metal material with a good light reflection property, such as silver or aluminum, so that the second electrode 120 may serve as not only an electrode structure that controls the organic light-emitting layer to emit light, but also the light reflection layer.

In the display panel provided by the embodiment of the present disclosure, since the light outgoing from the first substrate passes through the second substrate under the transmission mode, in order to improve the display effect, in one embodiment, the sub-pixel regions on the second substrate and the organic light-emitting units on the first substrate may have the same shape and size. Further, the sub-pixel regions on the second substrate may be directly face the organic light-emitting units on the first substrate one by one. Other embodiments are also feasible.

In one example, in order that the display panel may achieve a color displaying, the organic light-emitting units on the first substrate 100 may be color organic light-emitting units. Specifically, organic light-emitting units with at least three colors (e.g., red R, green G and blue B) may be arranged on the first substrate periodically and repeatedly, so as to achieve a color displaying in a case that the display panel is in the transmission-type display mode, and a black-and-white displaying in a case that the display panel is in the reflection-type display mode.

In another example, the organic light-emitting units on the first substrate 100 may be white organic light-emitting units (i.e., the first substrate 100 is a WOLED substrate). Further, in order to enable the display panel to achieve a color displaying, a color film substrate may be added therein. FIG. 6 illustrates a schematic diagram of another display panel provided by an embodiment of the present disclosure. Referring to FIG. 6, the display panel comprises a first substrate 100, a liquid crystal layer 200, a second substrate 300 and a polarizer 400 which are stacked sequentially, and an upper side and a lower side of the liquid crystal layer 200 may be further provided with an orientation layer (not illustrated), respectively.

In the embodiment, the first substrate 100 is a WOLED substrate, on which a plurality of white organic light-emitting units arranged in a matrix are provided, and a light reflection layer is further provided on a side of each organic light-emitting units away from the liquid crystal layer.

The second substrate 300 is configured to control deflections of liquid crystal molecules in the liquid crystal layer, and comprises a plurality of sub-pixel regions. The sub-pixel regions on the second substrate 300 directly face the organic light-emitting units on the first substrate 200 one by one.

In addition, a third substrate 500 is further provided at a light-outgoing side of the first substrate 100. The third substrate comprises a plurality of color filter units which directly face the organic light-emitting units on the first substrate one by one and have the same shape and size as the organic light-emitting units.

In the embodiment, the third substrate 500 comprises color filter units with at least three colors which are arranged on the third substrate periodically and repeatedly. For example, the third substrate may comprise red, green and blue filter units to implement the display panel with the RGB mode.

In one example, in order to reduce the color crossing between adjacent subpixels, the third substrate further comprises a black matrix layer for separating the plurality of color filter units from each other.

In this embodiment, the displaying principle of the display panel is the same as that of the display panel in FIG. 1, and it is omitted herein. In this embodiment, the third substrate is added at the light-outgoing side of the first substrate, and white light is converted into light with corresponding color through the third substrate, thereby achieving the color displaying of the display panel.

In one embodiment, in order to further reduce the color crossing between adjacent subpixels and improve the display effect, the third substrate may be arranged as being close to a display side of the display panel. For example, the third substrate may be arranged at a side of the second substrate away from the liquid crystal layer.

As described above, the display panel provided by the embodiments of the present disclosure can achieve a switching between the transmission-type display mode and the reflection-type display mode. In a case where the ambient light is weak, the display signal may be input to the first substrate, thereby achieving a transmission-type displaying of the display panel. In a case where the ambient light is strong, the display signal may be input to the second substrate, thereby achieving a reflection-type displaying of the display panel. By switching between different modes in the above way, the energy consumption can be reduced and the display quality can be improved.

In another aspect, the embodiments of the present disclosure further provide a display device, comprising the above display panel, wherein the display device provided by the embodiment of the present disclosure may be any product or part having a display function, such as a notebook computer display screen, a television, a digital photo frame, a cell phone, a tablet computer, etc.

It shall be noted, when the elements and the embodiments of the present disclosure are introduced, the articles ‘a’, ‘an’, ‘the’ and ‘said’ are intended to represent the existence of one or more elements.

The expressions ‘have’, ‘comprise’, ‘include’ and their grammatical varieties are used in a non-exclusive manner. Thus the expressions ‘A has B’, ‘A comprises B’ and ‘A includes B’ all indicate a fact that besides B, A further includes one or more additional components and/or constitute elements, and a condition that besides B, any other component, constitute element or member is not presented in A.

The terms ‘first’ and ‘second’ are only used for the purpose of description, rather than indicating or implying any relative importance.

The drawings could exaggerate the sizes of the layers and regions for clear illustrations. In addition, it shall be understood that when an element or layer is referred to as being ‘on’ or ‘above’ another element or layer, it may be directly located on other element, or there may be an intermediate layer; when an element or layer is referred to as being ‘under’ or ‘below’ another element or layer, it may be directly located under other element, or there may be one or more intermediate layer or element; and when an element or layer is referred to as being ‘between’ two layers or elements, it may be an unique layer between the two layers or elements, or there may be more than one intermediate layer or element. The similar reference signs denote the similar elements throughout the specification.

The above embodiments are just used to describe the present disclosure, and the present disclosure is not limited thereto. A person skilled in the art can make various changes and modifications without deviating from the spirit and scope of the present disclosure, thus any equivalent technical solution belongs to the present disclosure, and the patent protection scope of the present disclosure shall be determined by the claims.

1. A display panel, comprising a first substrate, a liquid crystal layer, a second substrate and a polarizer which are stacked sequentially;
a light reflection layer and a plurality of organic light-emitting units being provided on the first substrate, wherein the plurality of organic light-emitting units are located at a side of the light reflection layer close to the liquid crystal layer;
the second substrate is configured to control deflections of liquid crystal molecules in the liquid crystal layer, so as to control a polarization state of light passing through the liquid crystal layer.

2. The display panel according to claim 1, wherein the second substrate comprises a plurality of sub-pixel regions, each of which is provided with a thin film transistor and an electrode structure connected thereto; the electrode structure is configured to generate an electric field for controlling deflections of liquid crystal molecules in a region corresponding to the sub-pixel region in the liquid crystal layer.

3. The display panel according to claim 1, wherein the organic light-emitting unit comprises an organic light-emitting layer, a first electrode layer provided at a side of the organic light-emitting layer close to the liquid crystal layer, and a second electrode layer provided at a side of the organic light-emitting layer away from the liquid crystal layer.

4. The display panel according to claim 3, wherein the second electrode layer and the light reflection layer are the same structure, so as to multiplex the second electrode layer as the light reflection layer.

5. The display panel according to claim 1, wherein the plurality of organic light-emitting units are white organic light-emitting units.

6. The display panel according to claim 2, wherein the sub-pixel regions on the second substrate directly face the organic light-emitting units on the first substrate one by one.

7. The display panel according to claim 6, wherein the sub-pixel regions on the second substrate and the organic light-emitting units on the first substrate have the same shape and size.

8. The display panel according to claim 5, wherein the display panel further comprises a third substrate provided at a light-outgoing side of the first substrate; the third substrate comprises a plurality of color filter units which directly face the organic light-emitting units on the first substrate one by one.

9. The display panel according to claim 8, wherein the third substrate further comprises color filter units having at least three colors which are arranged on the third substrate periodically and repeatedly.

10. The display panel according to claim 8, wherein the third substrate further comprises a black matrix layer for separating the plurality of color filter units from each other.

11. The display panel according to claim 8, wherein the third substrate is provided at a side of the second substrate away from the liquid crystal layer.

12. The display panel according to claim 1, wherein the plurality of organic light-emitting units are color organic light-emitting units.

13. The display panel according to claim 12, wherein the first substrate comprises organic light-emitting units having at least three colors which are arranged on the first substrate periodically and repeatedly.

14. The display panel according to claim 1 further comprising a control unit configured to input a display signal to the first substrate or the second substrate, so that the display panel operates under a first display mode in a case that the display signal is input to the first substrate, and the display panel operates under a second display mode in a case that the display signal is input to the second substrate.

15. The display panel according to claim 14, wherein the first display mode is a transmission-type display mode, and the second display mode is a reflection-type display mode.

16. A display device, comprising the display panel according to claim 1.

17. The display device according to claim 16, wherein the second substrate comprises a plurality of sub-pixel regions, each of which is provided with a thin film transistor and an electrode structure connected thereto; the electrode structure is configured to generate an electric field for controlling deflections of liquid crystal molecules in a region corresponding to the sub-pixel region in the liquid crystal layer.

18. The display device according to claim 16, wherein the organic light-emitting unit comprises an organic light-emitting layer, a first electrode layer provided at a side of the organic light-emitting layer close to the liquid crystal layer, and a second electrode layer provided at a side of the organic light-emitting layer away from the liquid crystal layer.

19. The display device according to claim 18, wherein the second electrode layer and the light reflection layer are the same structure, so as to multiplex the second electrode layer as the light reflection layer.

20. The display device according to claim 17, wherein the sub-pixel regions on the second substrate directly face the organic light-emitting units on the first substrate one by one.
